(19) United States
(12) Patent Application Publication
(10) Pub. No.: US 2006/0238274 A1
(43) Pub. Date: Oct. 26, 2006

(54) Surface acoustic wave device

(75) Inventors: Sheng-Nan Huang, Feng Shan City (TW); Wen-Long Leu, Feng Shan City (TW); Chien-Heng Cheng, Feng Shan City (TW); Yu-Ching Huang, Feng Shan City (TW)

Correspondence Address: BANNER & WITCOFF, 1001 G STREET N W, SUITE 1100, WASHINGTON, DC, 20001, US

(73) Assignee: YCL ELECTRONICS CO., LTD., Feng Shan City (TW)

(21) Appl. No.: 11/111,938

(22) Filed: Apr. 22, 2005

(51) Int. Cl. H03H 9/00

(52) U.S. Cl. 333/193

(57) ABSTRACT

A SAW device includes: a SAW chip having a piezoelectric substrate and transmitting and receiving transducers; a circuit board formed with conductive inner contacts, each of which is connected electrically to a respective one of the transmitting and receiving transducers; a first adhesive-confining curb interconnecting the circuit board and the transmitting and receiving transducers and cooperating with the circuit board and the SAW chip to define an enclosed cavity thereamong; a second adhesive-confining curb surrounding the first adhesive-confining curb to define a sealing space therebetween; an adhesive body filling the sealing space; and a molding compound covering the SAW chip and connected sealingly to the second adhesive-confining curb.

### BACKGROUND OF THE INVENTION

1. Field of the Invention

This invention relates to a surface acoustic wave (SAW) device, more particularly to a SAW device that includes a SAW chip enclosed sealingly by an adhesive body.

2. Description of the Related Art

U.S. Pat. No. 5,059,848 discloses a SAW device that includes a carrier chip, a piezoelectric substrate formed on the carrier chip and formed with transducers thereon, a cover disposed over the piezoelectric substrate, and a glass frit seal interposed between and cooperating with the piezoelectric substrate and the cover to define an enclosed cavity thereamong. The transducers include thin-film bus bars that extend under the glass frit seal outwardly of the enclosed cavity, thereby enabling electrical interconnections between the transducers and associated impedance matching circuitry.

Due to the cost and infrastructure in supplying the known good chips, there is a need for a SAW device that is in the form of a package. Moreover, there is a need for a SAW chip to be connected directly to a circuit board to form the package.

### SUMMARY OF THE INVENTION

Therefore, the object of this invention is to provide a SAW device that is in the form of a package.

According to one aspect of the present invention, there is provided a SAW device that comprises: a SAW chip including a piezoelectric substrate that has a transducer surface, and transmitting and receiving transducers that are formed on the transducer surface, each of the transmitting and receiving transducers having an active portion and a connecting portion extending from the active portion; a circuit board spaced apart from the piezoelectric substrate, having an inner contact surface that faces the transducer surface of the piezoelectric substrate, and formed with conductive inner contacts on the inner contact surface, each of the inner contacts being connected electrically to the connecting portion of a respective one of the transmitting and receiving transducers; a first adhesive-confining curb interposed between and interconnecting the inner contact surface of the circuit board and the connecting portions of the transmitting and receiving transducers and cooperating with the circuit board and the SAW chip to define an enclosed cavity thereamong, the first adhesive-confining curb surrounding the enclosed cavity, the active portions of the transmitting and receiving transducers being confined in the enclosed cavity, the connecting portions of the transmitting and receiving transducers extending outwardly of the enclosed cavity; a second adhesive-confining curb formed on the inner contact surface of the circuit board and surrounding the first adhesive-confining curb to define a sealing space therebetween; an adhesive body filling the sealing space, bonded to the piezoelectric substrate, the circuit board, and the first adhesive-confining curb, and surrounding the first adhesive-confining curb; and a molding compound covering the SAW chip and connected sealingly to the second adhesive-confining curb.

According to another aspect of the present invention, there is provided a SAW device that comprises: a SAW chip including a piezoelectric substrate that has a transducer surface, and transmitting and receiving transducers that are formed on the transducer surface, each of the transmitting and receiving transducers having an active portion and a connecting portion extending from the active portion; a circuit board spaced apart from the piezoelectric substrate, having an inner contact surface that faces the transducer surface of the piezoelectric substrate, and formed with conductive inner contacts on the inner contact surface and a recess that is indented inwardly from the inner contact surface and that is disposed among the inner contacts, each of the inner contacts being connected electrically to the connecting portion of a respective one of the transmitting and receiving transducers, the circuit board and the piezoelectric substrate cooperatively defining a sealing space therebetween, the sealing space surrounding the inner contacts; an adhesive body filling the sealing space, bonded to the piezoelectric substrate and the circuit board, and cooperating with the piezoelectric substrate and the circuit board to define an enclosed cavity thereamong, the adhesive body surrounding the enclosed cavity, the recess forming a portion of the enclosed cavity, the active portions of the transmitting and receiving transducers being registered with the recess in a normal direction relative to the transducer surface of the piezoelectric substrate; and a molding compound covering the SAW chip.

### BRIEF DESCRIPTION OF THE DRAWINGS

Other features and advantages of the present invention will become apparent in the following detailed description of the preferred embodiments of the invention, with reference to the accompanying drawings. In the drawings:

FIG. 1 is a partly sectional view of the first preferred embodiment of a SAW device according to this invention; and

FIG. 2 is a partly sectional view of the second preferred embodiment of a SAW device according to this invention.

### DETAILED DESCRIPTION OF THE PREFERRED EMBODIMENTS

Before the present invention is described in greater detail, it should be noted that same reference numerals have been used to denote like elements throughout the specification.

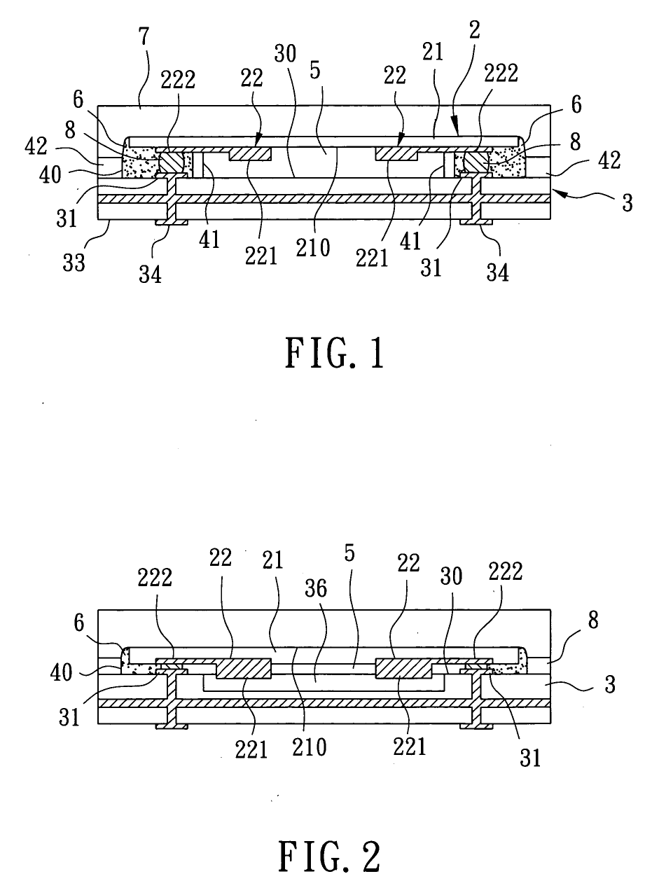

FIG. 1 illustrates the first preferred embodiment of a surface acoustic wave (SAW) device according to this invention for applications, such as mobile phones.

The SAW device includes: a SAW chip 2 including a piezoelectric substrate 21 that has a transducer surface 210, and transmitting and receiving transducers 22 that are formed on the transducer surface 210, each of the transmitting and receiving transducers 22 having an active portion 221 and a connecting portion 222 extending from the active portion 221; a circuit board 3 spaced apart from the piezoelectric substrate 21, having an inner contact surface 30 that faces the transducer surface 210 of the piezoelectric substrate 21, and formed with conductive inner contacts 31 on the inner contact surface 30, each of the inner contacts 31 being connected electrically to the connecting portion 222 of a respective one of the transmitting and receiving transducers 22; a first adhesive-confining curb 41 interposed between and interconnecting the inner contact surface 30 of the circuit board 3 and the connecting portions 222 of the transmitting and receiving transducers 22 and cooperating with the circuit board 3 and the SAW chip 2 to define an enclosed cavity 5 thereamong, the first adhesive-confining curb 41 surrounding the enclosed cavity 5, the active portions 221 of the transmitting and receiving transducers 22 being confined in the enclosed cavity 5, the connecting portions 222 of the transmitting and receiving transducers 22 extending outwardly of the enclosed cavity 5; a second adhesive-confining curb 42 formed on the inner contact surface 30 of the circuit board 3 and surrounding the first adhesive-confining curb 41 to define a sealing space 40 therebetween; an adhesive body 6 filling the sealing space 40, bonded to the piezoelectric substrate 21, the circuit board 3, and the first adhesive-confining curb 41, and surrounding the first adhesive-confining curb 41 which surrounds the enclosed cavity 5, the adhesive body 6 being made from an adhesive material; and a molding compound 7 covering the SAW chip 2 and connected sealingly to the second adhesive-confining curb 42. The active portion 221 of each of the transmitting and receiving transducers 22 includes metal-thin-film bus bars (not shown) for transmitting or receiving surface acoustic waves that propagate along the transducer surface of the piezoelectric substrate 21.

The first and second adhesive-confining curbs 41, 42 prevent the adhesive material from overflowing into the enclosed cavity 5 and outwardly of the circuit board 3 during formation of the adhesive body 6.

The adhesive body 6 is capable of preventing undesired dislocation of the assembly of the circuit board 3 and the SAW chip 2, and facilitates molding of the molding compound 7 over the SAW chip 2.

In this embodiment, the SAW device further includes solder bumps 8, each of which is disposed between and is connected to a respective one of the inner contacts 31 and the connecting portion 222 of a respective one of the transmitting and receiving transducers 22. The solder bumps 8 are enclosed by the adhesive body 6.

The circuit board 3 further has an outer contact surface 33 opposite to the inner contact surface 30, and is further formed with conductive outer contacts 34 on the outer contact surface 33. The outer contacts 34 are electrically and respectively connected to the inner contacts 31, and are adapted to be electrically connected to at least an external electrical component (not shown) through surface mounting techniques.

Preferably, the first and second adhesive-confining curbs 41, 42 are made from an insulative polymeric material.

FIG. 2 illustrates the second preferred embodiment of the SAW device according to this invention. The SAW device of this invention differs from the previous embodiment in that there is no first adhesive-confining curb 41 present and that a recess 36 is formed in and is indented inwardly from the inner contact surface 30 of the circuit board 3. The recess 36 in the circuit board 3 forms a main portion of the enclosed cavity 5, and is disposed among the inner contacts 31 of the circuit board 3. The active portions 221 of the transmitting and receiving transducers 22 are registered with the recess 36 in a normal direction relative to the transducer surface 210 of the piezoelectric substrate 21. The circuit board 3 and the piezoelectric substrate 21 cooperatively define the sealing space 40 therebetween. The sealing space 40 which is filled by the adhesive body 6 surrounds the inner contacts 31.

With the inclusion of the adhesive body 6 in the SAW device of this invention, the SAW chip 2 can be delivered in the form of a package, thereby facilitating subsequent mounting of the SAW device to an external circuit board using surface mounting techniques. Moreover, with the inclusion of the recess 36 in the circuit board 3 in the SAW device of this invention, the first adhesive-confining curb 41 can be dispensed with, thereby reducing the required processing steps and the manufacturing costs.

While the present invention has been described in connection with what is considered the most practical and preferred embodiments, it is understood that this invention is not limited to the disclosed embodiments but is intended to cover various arrangements included within the spirit and scope of the broadest interpretations and equivalent arrangements.

We claim:

1. A SAW device comprising:
a SAW chip including a piezoelectric substrate that has a transducer surface, and transmitting and receiving transducers that are formed on said transducer surface, each of said transmitting and receiving transducers having an active portion and a connecting portion extending from said active portion;
a circuit board spaced apart from said piezoelectric substrate, having an inner contact surface that faces said transducer surface of said piezoelectric substrate, and formed with conductive inner contacts on said inner contact surface, each of said inner contacts being connected electrically to said connecting portion of a respective one of said transmitting and receiving transducers;
a first adhesive-confining curb interposed between and interconnecting said inner contact surface of said circuit board and said connecting portions of said transmitting and receiving transducers and cooperating with said circuit board and said SAW chip to define an enclosed cavity thereamong, said first adhesive-confining curb surrounding said enclosed cavity, said active portions of said transmitting and receiving transducers being confined in said enclosed cavity, said connecting portions of said transmitting and receiving transducers extending outwardly of said enclosed cavity;
a second adhesive-confining curb formed on said inner contact surface of said circuit board and surrounding said first adhesive-confining curb to define a sealing space therebetween;
an adhesive body filling said sealing space, bonded to said piezoelectric substrate, said circuit board, and said first adhesive-confining curb, and surrounding said first adhesive-confining curb; and
a molding compound covering said SAW chip and connected sealingly to said second adhesive-confining curb.

2. The SAW device of claim 1, wherein said first and second adhesive-confining curbs are made from an insulative polymeric material.

3. The SAW device of claim 1, further comprising solder bumps, each of which is disposed between and is connected to a respective one of said inner contacts and said connecting portion of a respective one of said transmitting and receiving transducers, said solder bumps being enclosed by said adhesive body.

4. The SAW device of claim 1, wherein said circuit board further has an outer contact surface opposite to said inner contact surface, and is further formed with conductive outer contacts on said outer contact surface, said outer contacts being electrically and respectively connected to said inner contacts and being adapted to be electrically connected to at least an external electrical component.

5. A SAW device comprising:
a SAW chip including a piezoelectric substrate that has a transducer surface, and transmitting and receiving transducers that are formed on said transducer surface, each of said transmitting and receiving transducers having an active portion and a connecting portion extending from said active portion;
a circuit board spaced apart from said piezoelectric substrate, having an inner contact surface that faces said transducer surface of said piezoelectric substrate, and formed with conductive inner contacts on said inner contact surface and a recess that is indented inwardly from said inner contact surface and that is disposed among said inner contacts, each of said inner contacts being connected electrically to said connecting portion of a respective one of said transmitting and receiving transducers, said circuit board and said piezoelectric substrate cooperatively defining a sealing space therebetween, said sealing space surrounding said inner contacts;
an adhesive body filling said sealing space, bonded to said piezoelectric substrate and said circuit board, and cooperating with said piezoelectric substrate and said circuit board to define an enclosed cavity thereamong, said adhesive body surrounding said enclosed cavity, said recess forming a portion of said enclosed cavity, said active portions of said transmitting and receiving transducers being registered with said recess in a normal direction relative to said transducer surface of said piezoelectric substrate; and
a molding compound covering said SAW chip.

6. The SAW device of claim 5, further comprising an adhesive-confining curb that is formed on said inner contact surface of said circuit board, that surrounds and that is bonded to said adhesive body, and that is sealingly connected to said molding compound.

7. The SAW device of claim 5, wherein said adhesive-confining curbs is made from an insulative polymeric material.

8. The SAW device of claim 5, wherein said circuit board further has an outer contact surface opposite to said inner contact surface, and is further formed with conductive outer contacts on said outer contact surface, said outer contacts being electrically and respectively connected to said inner contacts and being adapted to be electrically connected to at least an external electrical component.
